(19) United States
(12) Patent Application Publication
(10) Pub. No.: US 2024/0349596 A1
(43) Pub. Date: Oct. 17, 2024

(54) PEROVSKITE PRECURSOR COMPOSITION

(71) Applicants: PARIS SCIENCES ET LETTRES, Paris (FR); ECOLE NATIONALE SUPERIEURE DE CHIMIE DE PARIS, Paris (FR); CENTRE NATIONAL DE LA RECHERCHE SCIENTIFIQUE, Paris (FR)

(72) Inventors: Thierry PAUPORTÉ, VINCENNES (FR); Tao ZHU, Paris (FR)

(21) Appl. No.: 18/291,220

(22) PCT Filed: Jun. 28, 2022
(86) PCT No.: PCT/FR2022/051277

§ 371 Date: Jan. 22, 2024

(30) Foreign Application Priority Data
Jul. 23, 2021 (FR) 2107987

(51) Int. Cl. H10K 85/50; H10K 30/30; H10K 71/12

(52) U.S. Cl. CPC H10K 85/50; H10K 30/30; H10K 71/12

(57) ABSTRACT

The invention relates to a perovskite precursor composition, wherein each compound is defined by the following formula (I):

(A′)₂FAₙ₋₁MA_{(n-1)y}Pbₙ₍₁₊ₓ₎Iₙ₍₃₊₂ₓ₎₊₁Cl_{y(n-1)} (I)

where
A′ is an organic ammonium compound, preferably selected from benzylammonium, phenylethylammonium, n-propylammonium, phenylammonium, histammonium, cyclopentylammonium, cyclohexylammonium, cyclohexylmethylammonium, 4-ammonium butyric acid, 5-ammonium valeric acid, or isobutylammonium,
FA is formamidinium,
MA is methylammonium,
n is between 3 and 9,
x is between 0.1 and 0.25, and
y is between 0.2 and 0.6.

### TECHNICAL FIELD

The present invention relates to the field of perovskites. More particularly, the invention relates to a composition of precursors of a halogenated perovskite for the manufacture of a continuous layer of halogenated perovskite of small size and of very high stability intended to be used in a photosensitive and/or optoelectronic device.

The term “perovskite of small size”, in the sense of the present invention, refers to a perovskite consisting of sheets of several organic/inorganic hybrid layers which are superimposed. For example, as perovskites of small size, pseudo-2D perovskites can be cited.

The term “high stability”, in the sense of the present invention, refers to a perovskite that resists external aggressive agents such as moisture and oxygen.

### PRIOR ART

Perovskite originally refers to the mineral CaTiO₃ (calcium titanate). Many oxides of formula ABO₃ adopt a perovskite-type structure. Organic-inorganic hybrid perovskites ABX₃ have been developed to be applied to photosensitive, photovoltaic devices in particular. These can be deposited in thin layers from halogenated perovskite precursor compositions. The crystallization temperature of the layers of halogenated perovskites is relatively low (<160° C.) and it is possible to modulate their band gap energy by adjusting the precursor composition. Their charge mobility is high. However, the conventional halogenated perovskites obtained are not very stable, which hinders their development on an industrial scale.

To increase stability, perovskite ABX₃ can be deposited in a mesoporous matrix which may in particular be comprised in photovoltaic cells and which may, for example, be a triple mesoporous layer based on TiO₂/ZrO₂/carbon^{[1]}. However, the photovoltaic yields of this type of photovoltaic cell are low (<15%).

Another solution consists of removing the most harmful compounds from the perovskite precursor composition to improve the stability of the perovskite layer taken from the precursor composition. For example, currently offered solutions consist of reducing, or even eliminating, the organic component generally included in perovskite precursor compositions, in particular methylammonium, or even formamidinium. However, the simple removal of these compounds is not sufficient to guarantee the stability of the perovskite layer obtained, and in particular its moisture stability, which remains problematic. It should also be noted that it is currently difficult to completely eliminate the organic component of perovskite precursor compositions and to replace it with an elemental cation since no elemental cation is sufficiently large (Cs⁺=167 pm, Rb⁺=152 pm, K⁺=133 pm) for such a replacement (methylammonium: 217 pm, formamidinium: +253 μm).

Also to increase stability, another solution consists of reducing the size of the perovskite to obtain perovskite layers of lower size. This reduction is made possible by adding into the perovskite precursor composition another organic compound of greater size than those already present in the composition. At present, as other organic compounds of greater size, thiol compounds are known to reinforce the interactions between inorganic sheets constituting at least part of the perovskite layer obtained, or fluorinated compounds to increase the robustness of the perovskite materials obtained.

However, with layers of perovskites of small size, it is necessary to obtain a perovskite having a homogeneous phase. In addition, the perovskite layers must be homogeneous in composition, which is problematic with the manufacturing methods currently implemented.

### DESCRIPTION OF THE INVENTION

One of the aims of the invention is to remedy the shortcomings of perovskite layer manufacturing methods of the prior art.

According to a first aspect, the invention relates to a perovskite precursor composition, wherein each compound is defined by the following formula (I):

(A′)₂FAₙ₋₁MA_{(n-1)y}Pbₙ₍₁₊ₓ₎Iₙ₍₃₊₂ₓ₎₊₁Cl_{y(n-1)} (I)
where
A′ is an organic ammonium compound, preferably selected from benzylammonium, phenylethylammonium, n-propylammonium, phenylammonium, histammonium, cyclopentylammonium, cyclohexylammonium, cyclohexylmethylammonium, 4-ammonium butyric acid, 5-ammonium valeric acid, or isobutylammonium,
FA is formamidinium,
MA is methylammonium,
n is between 3 and 9,
x is between 0.1 and 0.25,
y is between 0.2 and 0.6,
   the precursor composition comprising:
lead iodide at a stoichiometric proportion of n(1+x) in the precursor composition, iodide of the organic ammonium compound at a stoichiometric proportion of 2 in the precursor composition,
formamidinium iodide at a stoichiometric proportion of n−1 in the precursor composition, and
a polar aprotic solvent,
the composition being characterized in that the composition further comprises methyl ammonium chloride at a molar concentration of between 20 and 60% relative to the molar concentration of formamidinium iodide in the precursor composition, and in that the molar concentration of lead iodide is between 0.6 and 1.5 mol/L.

According to this first aspect, the invention, on the one hand, to implement a homogeneous composition of a perovskite precursor, which is non-stoichiometric characterized by an excessive presence of PbI₂, and which is adapted to the manufacture of a perovskite layer, and on the other hand, to manufacture halogenated perovskites of small size, which ultimately makes it possible to improve the stability of the perovskite layer obtained due to the presence of another cation provided by the organic ammonium compound A′, which makes it possible to obtain high yields for this type of composition.

Such a composition allows the prior control, during the formation of the perovskite layer, of the crystallization. Such a composition makes it possible to control the dimensionality and to reduce the n dispersion of the perovskite obtained after application of this composition. Thus, the stability of the perovskite layer obtained is improved.

It may be advantageous to use specific polar aprotic solvents to prepare solutions in which the precursors are dissolved optimally. Therefore, the polar aprotic solvent may be selected from N, N-dimethylformamide, N-methyl-2-pyrrolidone, dichloromethane, tetrahydrofuran, ethyl acetate, acetonitrile, dimethyl sulfoxide, acetone, hexamethylphosphorous triamide, gamma-butyrolactone, or is a mixture of the aforementioned polar aprotic solvents.

Preferably, the polar aprotic solvent is a mixture of solvents comprising N,N-dimethylformamide and dimethyl sulfoxide. Preferably, in this mixture of solvents, the proportion by volume of N, N-dimethylformamide in the mixture of total solvents may be between 75% and 90% and the volume proportion of dimethyl sulfoxide in the mixture of total solvents may be between 10% and 25%.

It may be advantageous to obtain a perovskite having both sufficient performance and stability to be used in photosensitive and/or optoelectronic devices. Therefore, n may preferably be between 5 and 7. Devices having photovoltaic conversion yields approximately equal to 17.3% can be obtained for example.

Correspondingly, the invention also relates to a method for producing the composition as described above, the method comprising the following steps:
a) preparing a first solution wherein each compound is defined by the formula (II) (A′)₂FAₙ₋₁PbₙI₃ₙ₊₁, said preparation being carried out by bring into contact at least the iodide of the organic ammonium compound, formamidinium iodide and lead iodide, the organic ammonium compound preferably being selected from benzyl ammonium, phenethylammonium, n-propylammonium, phenylammonium, histammonium, cyclopentylammonium, cyclohexylammonium, cyclohexylmethylammonium, 4-ammonium butyric acid, 5-ammonium valeric acid, or isobutyl ammonium,
   the first solution being characterized in that the stoichiometry of each compound is as follows:
the stoichiometric proportion of the iodide of the organic ammonium compound in the composition is 2,
the stoichiometric proportion of formamidinium iodide in the composition is n−1,
the stoichiometric proportion of lead iodide in the composition is n,
with n being between 3 and 9,
b) preparing a second solution by bringing at least the compounds below into contact:
   lead iodide present in the second solution at a molar ratio relative to lead iodide in the first solution of between 10% and 25%,
   methyl ammonium chloride present in the second solution at a molar ratio relative to formamidinium iodide in the first solution of between 20% and 60%,
c) forming a third solution wherein the molar concentration of lead iodide is between 0.6 mol/L and 1.5 mol/L by mixing said first solution and said second solution with at least one polar aprotic solvent.

By implementing such a production method, a homogeneous composition is obtained. Furthermore, if the third solution has a molar concentration of lead iodide greater than 1.5 mol/L, the perovskite layer obtained using the precursor composition will have impurity inclusions and this will result in a discontinuous layer of perovskite. If the third solution has a molar concentration of lead iodide less than 0.6 mol/L, the perovskite layer obtained using the precursor composition will be too thin and this will result in a high risk of obtaining a perovskite layer that is itself also discontinuous.

It should be noted that in the first solution, the molar concentration of lead iodide ([PbI₂]) is equal to n and in the second solution, the molar concentration of lead iodide is [PbI₂] between 10% and 25% relative to the molar concentration of lead iodide in the first solution. Thus, the molar concentration of lead iodide in the third solution is equal to n+nx, equivalent to n(1+x), with x comprised between 0.1 and 0.25.

It may be advantageous to dissolve all the solid precursors contained in the third solution in order to obtain a perovskite layer which is homogeneous and which has a relatively pure phase. Therefore, the method may further comprise, after step c) of mixing, a step d) of stirring said third solution for a period of between 1 hour and 5 hours at room temperature.

Preferably, the step d) of stirring the third solution can be carried out in an inert atmosphere.

According to a second aspect, the invention relates to the manufacture of a continuous layer of perovskite, the method comprising the following steps:
depositing the composition as defined above on a support to obtain a perovskite precursor layer; and
annealing heat treatment at a temperature between 8° and 250° C. for 10 min at 2 hours of the perovskite precursor layer to obtain a continuous layer of perovskite.

It should be noted that the deposition step can be carried out by a flat die process, by spin coating, by spraying, or by blade coating, or by any technique using a spin coating device, a slot die, vacuum evaporation, inkjet printing, doctor blade or even pulsed laser deposition.

It should also be noted that the annealing heat treatment step makes it possible to crystallize the precursor layer in order to obtain a perovskite layer. This crystallization is allowed by the growth of the grains and also by the evaporation of the solvents and at least part of the methyl ammonium chloride contained in the precursor layer.

Thus, during the implementation of the annealing heat treatment step, there is partial or even quasi-total elimination of methyl ammonium and chloride. The stoichiometry of the perovskite thus obtained is therefore not that of the precursor composition.

According to a third aspect, the invention relates to a continuous layer of perovskite obtained by the method as defined above.

This perovskite layer has a homogeneous phase and is of small size.

It may be advantageous to use this perovskite layer in particular in the fields of photovoltaics or light-emitting. Therefore, the continuous layer of perovskite may be a thin layer, that is, a layer defined by a thickness of less than 1 μm.

According to a fourth aspect, the invention relates to a use of a composition as defined above to obtain a continuous layer of perovskite.

According to a fifth aspect, the invention relates to a photosensitive and/or optoelectronic device comprising at least one continuous layer of perovskite as defined above.

For example, the photosensitive and/or optoelectronic device may be a photovoltaic cell, a photodetector or a light-emitting diode.

Further advantages and features of the present invention will be apparent from the following description, made with reference to the following examples and the attached figures in which:

FIG. 1 shows photographs highlighting the evolution in ambient air of a photovoltaic cell comprising two layers of perovskites (40 m % and 20 m %) resulting from a composition according to the invention relative to a photovoltaic cell comprising a perovskite layer (0%) obtained by a method different from that of the invention,

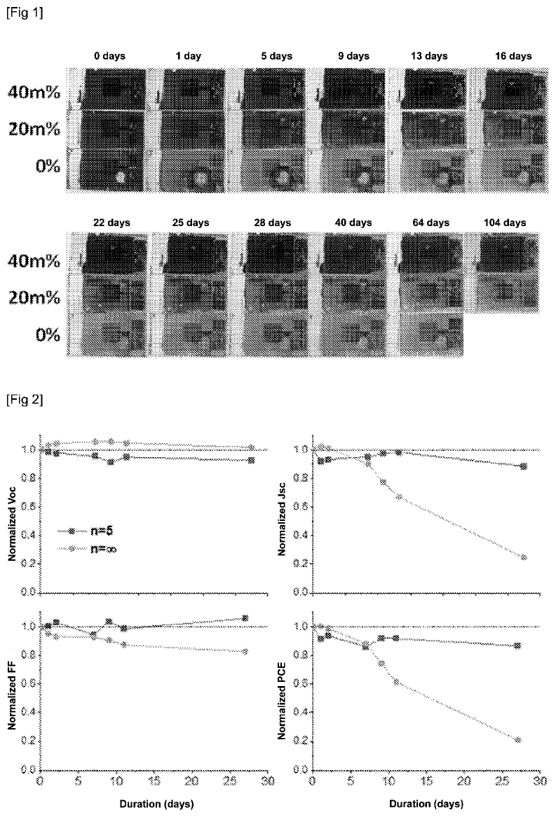

FIG. 2 shows curves representing current-voltage characteristics, after having been stored under ambient conditions, of a photovoltaic cell comprising a layer of perovskite resulting from a composition according to the invention relative to a photovoltaic cell comprising a layer of perovskite obtained by a method different from that of the invention,

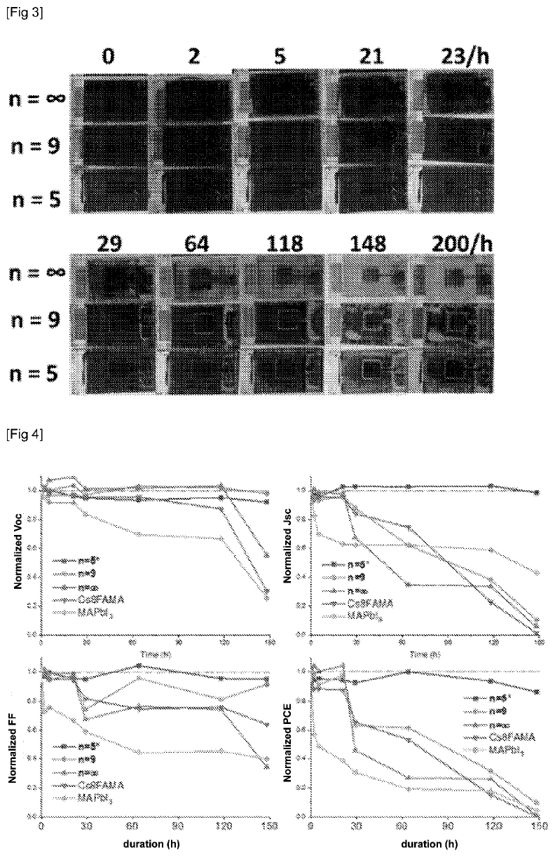

FIG. 3 shows photographs highlighting the evolution in a very humid atmosphere (>90% RH) of a photovoltaic cell comprising a layer of perovskite resulting from a composition according to the invention relative to photovoltaic cells comprising a layer of perovskite obtained by a method different from that of the invention,

FIG. 4 shows curves representing current-voltage characteristics, after having been stored in a very humid atmosphere (>90% RH), of a photovoltaic cell comprising a layer of perovskite resulting from a composition according to the invention relative to photovoltaic cells comprising a layer of perovskite obtained by a method different from that of the invention,

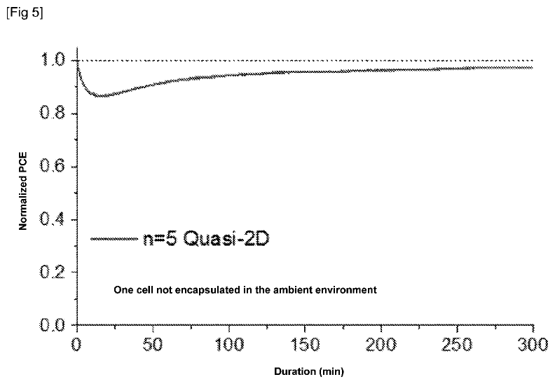

FIG. 5 shows a curve representing the maximum yield of a photovoltaic cell comprising a layer of perovskite resulting from a composition according to the invention.

### PRODUCTS

formamidinium iodide sold by Greatcell Energy
lead iodide sold by Tci Europe N.V.
iodide of the organic ammonium compound;
   benzylamine hydroiodide (BEI) sold by Tci Europe N.V.
methyl ammonium chloride sold by Greatcell Energy
polar aprotic solvents:
   N, N-dimethylformamide (DMF) sold by Sigma Aldrich
   dimethyl sulfoxide (DMSO) sold by Alfa Aesar

### Devices

a spin coating device designated by the trade name SPS POLOS SPIN150i, sold by S.P.S. bvba.

### Tests

The performances of the photovoltaic cells were obtained from the current-potential curves measured under an illumination AM 1.5G 100 mW/cm⁻² emitted using a Sun 2000 solar simulation apparatus sold by Abet Technologies.

The stability of the cells was evaluated as follows:
by tracking the color and appearance of the non-encapsulated photovoltaic cells stored in ambient air for 104 days;
by tracking the photovoltaic parameters and efficiency of the cells stored in the ambient air for a period of 28 days;
by tracking the color and appearance of the non-encapsulated photovoltaic cells stored in a very humid atmosphere of 90% RH for 200 h;
by tracking the photovoltaic efficiency and parameters of the non-encapsulated cells stored in a very humid atmosphere (>90% RH) for a duration of 150 h;
by tracking for 5 h, under an illumination AM 1.5G 100 mW/cm⁻², the photovoltaic output of the photovoltaic cell comprising a layer according to the invention.

### Examples

Examples of perovskite layers obtained using precursor compositions manufactured according to an embodiment according to the invention or not, as indicated below, were obtained from precursor compositions in which formamidinium iodide, lead iodide, iodide of the organic ammonium compound, and methyl ammonium chloride were mixed with a mixture of solvents comprising N,N-dimethylformamide (DMF) (for example at a volume proportion equivalent to 80% relative to the total volume) and dimethyl sulfoxide (DMSO) (for example at a volume proportion equivalent to 20% relative to the total volume).

In particular, for the production of these perovskite precursor compositions, a first solution and a second solution are prepared that are subsequently mixed together.

The first solution is in particular composed of benzylamine hydroiodide (BEI), formamidinium iodide (FAI) and lead iodide (PbI₂).

In the following, only the method making it possible to obtain compo2 and compo3 and use them are within the scope of the invention. The methods making it possible to obtain compo1, compo4 and compo5 are comparative examples not carried out according to the invention.

Examples of first solutions firstS1, firstS2, firstS3, firstS4 and firstS5 are indicated in Table 1 below:

TABLE 1

| Designation of 1st | | | |
|---|---|---|---|
| solution | BEI in mg | FAI in mg | Pbl₂ in mg |
| firstS1 | 50.92 | 74.51 | 236.49 |
| firstS2 | 50.92 | 74.51 | 236.49 |
| firstS3 | 50.92 | 74.51 | 236.49 |
| firstS4 | 31.3 | 91.8 | 276.6 |
| firstS5 | 0 | 103.18 | 276.6 |

Examples of second solutions secS1, secS2, secS3, secS4 and secS5 are indicated in Table 2 below:

TABLE 2

| Designation of 2nd solution | Pbl₂ in mg | MACl in mg |
|---|---|---|
| secS1 | 63.16 | 0 |
| secS2 | 63.16 | 5.85 |
| secS3 | 63.16 | 11.7 |
| secS4 | 0 | 12.98 |
| twoS5 | 0 | 14.6 |

Next, the following are brought into contact:
firstS1 with secS1 to obtain S1,
firstS2 with secS2 to obtain S2,
firstS3 with secS3 to obtain S3,
firstS4 with secS4 to obtain S4, and
firstS5 with secS5 to obtain S5.

Finally, each of the solutions obtained S1, S2, S3, S4 and S5 is mixed with a mixture of solvents consisting of 400 μL of N,N-dimethylformamide (DMF) and 100 μL of dimethyl sulfoxide (DMSO) in order to obtain, respectively, Compo1, Compo2, Compo3, Compo4 and Compo5 having the compositions indicated in Table 3:

TABLE 3

| Designation of | | | | | | | | |
|---|---|---|---|---|---|---|---|---|
| the precursor | | | | | Pbl₂ in | | | DMF/DMSO |
| compositions | BEI in mol/L | | FAI in mol/L | | mol/L | MACl in mol/L | | in μL |
| Compo1 | 0.432 | mol/L | 0.866 | mol/L | 1.3 mol/L | 0 | mol/L | 500 μL |
| Compo2 | 0.432 | mol/L | 0.866 | mol/L | 1.3 mol/L | 0.172 | mol/L | 500 μL |
| Compo3 | 0.432 | mol/L | 0.866 | mol/L | 1.3 mol/L | 0.344 | mol/L | 500 μL |
| Compo4 | 0.2666 | mol/L | 1.068 | mol/L | 1.2 mol/L | 0.384 | mol/L | 500 μL |
| Compo5 | 0 | mol/L | 1.2 | mol/L | 1.2 mol/L | 0.432 | mol/L | 500 μL |

Compo2 and Compo3 are compositions obtained according to the invention and comprise methyl ammonium chloride respectively at a molar concentration of about 20% and 40% relative to the molar concentration of formamidinium iodide.

Each of compositions Compo1, Compo2, Compo3, Compo4 and Compo5 are then stirred at room temperature for 2 h to 5 h in a glove box under N₂. The other steps are the same as those described in the protocol described above.

In particular, each of the compositions obtained is defined by the following formulas:

(n=5, x=0.2, y=0): (A′)₂FA₄MA₀Pb₆I₁₈Cl₀ Compo 1

(n in the range between 3 and 9, x in the range between 0.1 and 0.25 and y outside the range between 0.2 and 0.6).

(n=5, x=0.2, y=0.2): (A′)₂FA₄MA_{0.8}Pb₆I₁₈Cl_{0.8} Compo 2

(n in the range between 3 and 9, x in the range between 0.1 and 0.25 and y within the range between 0.2 and 0.6).

(n=5, x=0.2, y=0.4): (A′)₂FA₄MA_{1.6}Pb₆I₁₈Cl_{1.6} Compo 3

(n in the range between 3 and 9, x in the range between 0.1 and 0.25 and y within the range between 0.2 and 0.6).

(n=9, x=0, y=0.36): (A′)₂FA₈MA_{2.88}Pb₉I₂₈Cl_{2.88} Compo 4

(n within the range between 3 and 9, x within the range between 0.1 and 0.25 and y within the range between 0.2 and 0.6).

(n=∞, x=0, y=0.36): FAMA_{0.36}PbI₃Cl_{0.36} Compo 5

(n within the range between 3 and 9, x within the range between 0.1 and 0.25 and y within the range between 0.2 and 0.6).

### Making the Layers

Next, all the perovskite layers according to the exemplary embodiments were manufactured in a dry air box (RH≤10%).

To manufacture each of the layers of the examples below, 50 μL of each of the compositions of precursor Compo1, Compo2, Compo3, Compo4 and Compo5 as prepared was entered and was applied to a substrate consisting of an assembly comprising a layer of glass, a layer of fluorine-doped tin oxide (FTO) and one or two layers of TiO₂.

Then, each of these substrates coated with Compo1, Compo2, Compo3, Compo4 or Compo5 is deposited in the “spin coater” deposition apparatus programmed so as to operate at a speed approximately equal to 1000 rpm for 10 s and then at a speed approximately equal to 6000 rpm for 30s. In parallel to the deposits of these coated substrates, 100 μL of chlorobenzene was ejected onto each of the layers Compo1, Compo2, Compo3, Compo4 and Compo5 after 20 s following the start of the spin-coater. This step makes it possible to reduce the solubility of the precursors in solution and to form a precursor layer which then will give, during the annealing, the perovskite.

After the operation of the spin-coater, each of the coated substrates is placed on a heating plate, the setpoint temperature of which is approximately equal to 153° C. (screen temperature). The duration of such an annealing heat treatment is approximately 13 min. After this heat treatment, perovskite layers are obtained.

The performances of the perovskite layers resulting from the Compo1 (n=5), Compo2 (n=5), Compo3 (n=5), Compo4 (n=9) or Compo5 (n=) are shown in Table 4 below using results of tests carried out on photovoltaic cells comprising, inter alia, each of these perovskite layers.

In particular, each of these photovoltaic cells consists of: glass/FTO/compact layer of TiO₂ (20 nm)/porous layer of TiO₂ (120 nm)/Perovskite (350 nm-420 nm)/Spiro-OMeTAD (200 nm)/Au (60 nm):

TABLE 4

| | Photovoltaic conversion |
|---|---|
| Perovskite in the photovoltaic cell | efficiency (%) |
| Compo1 | 13.01 |
| Compo2 | 14.14 |
| Compo3 | 17.32 |
| Compo4 | 17.68 |
| Compo5 | 20.84 |

### Stability Tests:

As indicated in FIG. 1, the photovoltaic cell comprising a perovskite layer derived from compo1 (0%, n=5) does not retain the brown-black color over the duration of the test contrary to the photovoltaic cell comprising a layer of perovskite resulting from compo2 (20 m %, n=5) and compo3 (40 m %, n=5).

Photovoltaic cells comprising a layer derived from compo3 (n=5, according to the invention) and compo5 (n=∞) corresponding to a 3D perovskite) were stored under ambient conditions and their current-voltage characteristics were measured over 28 days (see FIG. 2).

The photovoltaic cells comprising a layer resulting from compo3 (n=5, according to the invention), compo4 (n=9) and compo5 (n=∞) were stored in a very humid atmosphere (>90% RH). Their appearance has changed as shown in FIG. 3. It will be noted that the photovoltaic cell comprising a layer derived from compo3 retains its black color in a very humid atmosphere.

And the photovoltaic performances (parameters of the current-voltage curves) of these photovoltaic cells changed as indicated in FIG. 4.

MAPbI₃ and Cs₈FAMA are two 3D perovskites. These are obtained as described in the scientific article [4].

In particular, for the MAPbI₃ perovskite, a layer of MAPbI₃ is prepared by producing a precursor solution MAPI 1.45 M by mixing 668.5 mg of PbI₂ and 230.5 mg of MAI in 1 mL of DMSO. The solution obtained is then stirred and maintained at 100° C. for 2h before use. The spincoating program was 1000 rpm for 10s and 6000 rpm for 30s. Next, 100 μL of chlorobenzene were injected at 30 s after the start of the activation of spincoating. Finally, the layers were annealed on a hot plate at 105° C. for 60 minutes.

Regarding Cs₈FAMA is prepared a precursor solution corresponding to a perovskite layer composition CS_{0.08}FA_{0.80}MA_{0.12}Pb(I_{0.88}Br₀₁₂)₃. To begin, 179 mg of formamidinium iodide (FAI), 17.4 mg of methyl ammonium bromide (MABr), 27.0 mg of CsI, 548 mg of PbI₂ and 57.1 mg of PbBr₂ are mixed in 220 μL of DMSO and 780 μL of DMF. The solution obtained is then stirred for a minimum of 3-4 h at room temperature in a glove box filled with N₂. Then samples of 29, 30, 31 and 45 μL of this solution were placed on top of the substrates. A two-step spincoating program was employed: first a rotation at 1000 rpm for 10 s, then at 6000 rpm for 30 s. 100 μL of chlorobenzene were injected 20s after the start of the activation of spincoating. The films obtained were then annealed at 105° C. for 1 h in a dry atmosphere.

After 150 h, the photovoltaic cell comprising a layer derived from compo3 loses only 15% of its initial performance when the other cells have yields of less than 15%.

The maximum efficiency of the photovoltaic cell comprising a layer derived from compo3 was monitored for 5 h under an illumination of AM 1.5G 100 mW/cm² as shown in FIG. 5.

All these measurements show a very high stability of the photovoltaic cells comprising a perovskite layer according to the invention.

### LIST OF REFERENCES

[1] Anyi Mei, Yusong Sheng, Yue Ming, Yue Hu, Yaoguang Rong, Weihua Zhang, Guangren Na, Chengbo Tian, Shuang Liu, Satoshi Uchida, Tae-Woong Kim, Yongbo Yuan, Lijun Zhang, Yinhua Zhou, Hongwei Han, “Stabilizing Perovskite Solar Cells to IEC61215: 2016 Standards with over 9,000-h Operational Tracking”, Joule, Volume 4, Issue 12, Dec. 16, 2020, Pages 2646-2660.
[2] Hui Ren, Shidong Yu, Lingfeng Chao, Yingdong Xia, Yuanhui Sun, Shouwei Zuo, Fan Li, Tingting Niu, Yingguo Yang, Huanxin Ju, Bixin Li, Haiyan Du, Xingyu Gao, Jing Zhang, Jianpu Wang, Lijun Zhang, Yonghua Chen, Wei Huang, “Efficient and stable Ruddlesden-Popper perovskite solar cell with tailored interlayer molecular interaction”, nature photonics, Volume 14, Jan. 13, 2020, Pages 154-163.
[3] Sajjad Ahmad, Ping Fu, Shuwen Yu, Qing Yang, Xuan Liu, Xuchao Wang, Xiuli Wang, Xin Guo, Can Li, “Dion-Jacobson Phase 2D Layered Perovskites for Solar Cells with Ultrahigh Stability”, Joule, Volume 3, Issue 3, Mar. 20, 2019, Pages 794-806.
[4] Daming Zheng, Tao Zhu, Thierry Pauporte, “Using Mnovalent-to trivalent-Cation Hybrid Perovskites for Producing High-Efficiency Solar Cells: Electrical Response, Impedance, and Stability” ACS Appl. Energy Matter. 2020, 3, 10349-10361 DOI.

1. A perovskite precursor composition, wherein each compound is defined by the following formula (I):
(A′)₂FAₙ₋₁MA_{(n-1)y}Pbₙ₍₁₊ₓ₎Iₙ₍₃₊₂ₓ₎₊₁Cl_{y(n-1)} (I)
in which
A′ is an organic ammonium compound, preferably selected from benzylammonium, phenylethylammonium, n-propylammonium, phenylammonium, histammonium, cyclopentylammonium, cyclohexylammonium, cyclohexylmethylammonium, 4-ammonium butyric acid, 5-ammonium valeric acid, or isobutylammonium,
FA is formamidinium,
MA is methylammonium,
n is between 3 and 9,
x is between 0.1 and 0.25,
y is between 0.2 and 0.6,
said precursor composition comprising:
lead iodide at a stoichiometric proportion of n(1+x) in the precursor composition,
iodide of the organic ammonium compound at a stoichiometric proportion of 2 in the precursor composition,
formamidinium iodide at a stoichiometric proportion of n−1 in the precursor composition, and
a polar aprotic solvent,
the composition being characterized in that the composition further comprises methyl ammonium chloride at a molar concentration of between 20 and 60% relative to the molar concentration of formamidinium iodide in the precursor composition, and
in that the molar concentration of lead iodide is between 0.6 and 1.5 mol/L.

2. The composition according to claim 1, wherein said polar aprotic solvent is selected from N,N-dimethylformamide, N-methyl-2-pyrrolidone, dichloromethane, tetrahydrofuran, ethyl acetate, acetonitrile, dimethyl sulfoxide, acetone, hexamethylphosphorous triamide, gamma-butyrolactone, or is a mixture of the aforementioned polar aprotic solvents.

3. The composition according to claim 1, wherein n is between 5 and 7.

4. A method for producing the composition according to claim 1, said method comprising the following steps:
a) preparing a first solution wherein each compound is defined by the formula (II) (A′)₂FAₙ₋₁PbₙI₃ₙ₊₁, said preparation being carried out by bring into contact at least the iodide of an organic ammonium compound, formamidinium iodide and lead iodide, the organic ammonium compound preferably being selected from benzyl ammonium, phenethylammonium, n-propylammonium, phenylammonium, histammonium, cyclopentylammonium, cyclohexylammonium, cyclohexylmethylammonium, 4-ammonium butyric acid, 5-ammonium valeric acid, or isobutyl ammonium,
the first solution being characterized in that the stoichiometry of each compound is as follows:
the stoichiometric proportion of the iodide of the organic ammonium compound in the composition is 2,
the stoichiometric proportion of formamidinium iodide in the composition is n−1,
the stoichiometric proportion of lead iodide in the composition is n,
with n being between 3 and 9,
b) preparing a second solution by bringing at least the compounds below into contact:
lead iodide present in the second solution at a molar ratio relative to lead iodide in the first solution of between 10% and 25%,
methyl ammonium chloride present in the second solution at a molar ratio relative to formamidinium iodide in the first solution of between 20% and 60%,
c) forming a third solution wherein the molar concentration of lead iodide is between 0.6 mol/L and 1.5 mol/L by mixing said first solution and said second solution with at least one polar aprotic solvent.

5. The method according to claim 4, further comprising, after step c) of mixing, a step d) of stirring said third solution for a period of between 1 hour and 5 hours at room temperature.

6. The method for manufacturing a continuous layer of perovskite, the method comprising the following steps:
depositing the composition as defined according to claim 1 on a support to obtain a perovskite precursor layer; and
annealing heat treatment at a temperature between 8° and 250° C. for 10 min at 2 hours of the perovskite precursor layer to obtain a continuous layer of perovskite.

7. The use of a composition according to claim 1 to obtain a continuous layer of perovskite.

8. A photosensitive and/or optoelectronic device comprising at least one continuous layer of perovskite obtained according to claim 6.
